(19) United States
(12) Patent Application Publication
(10) Pub. No.: US 2017/0077957 A1
(43) Pub. Date: Mar. 16, 2017

(54) ERROR CORRECTION DEVICE AND ERROR CORRECTION METHOD

(71) Applicant: SK hynix Inc., Icheon-si Gyeonggi-do (KR)

(72) Inventor: Hyuk Choong KANG, Seongnam-si Gyeonggi-do (KR)

(21) Appl. No.: 15/058,265

(22) Filed: Mar. 2, 2016

(30) Foreign Application Priority Data
Sep. 14, 2015 (KR) 10-2015-0129829

(51) Int. Cl. H03M 13/29; G11C 29/52; G06F 11/10

(52) U.S. Cl. CPC H03M 13/2906; G06F 11/1068; G11C 29/52

(57) ABSTRACT

An error correction circuit may include a single error correction circuit configured to read unit write data indicated by a unit designation signal from a memory cell array as read data, correct a single bit error, and provide corrected data. The error correction circuit may include a comparison unit configured to compare the corrected data with the unit write data and provide a comparison result. The error correction circuit may include a control unit configured to update and generate the unit designation signal on the basis of the comparison result. The unit designation signal may be generated to indicate at least one of a plurality of segmented data obtained by dividing the unit write data.

### CROSS-REFERENCES TO RELATED APPLICATION

The present application claims priority under 35 U.S.C. §119(a) to Korean application number 10-2015-0129829, filed on Sep. 14, 2015, in the Korean Intellectual Property Office, which is incorporated herein by reference in its entirety.

### BACKGROUND

1. Technical Field

Various embodiments generally relate to an error correction device and an error correction method.

2. Related Art

In a semiconductor device including a memory cell array for data storage, even though desired data is written, there may be an error in the value of data actually written in the memory cell array. This error in the memory cell array may be due to a deviation in a fabrication process of the memory cell array, a parasitic component of a circuit, and/or the like.

For error correction of data desired to be actually written and data read from the memory cell array, an error correction code may be generated on the basis of data to be written, and the error correction code and the data may be written in the memory cell array. The written data and the error correction code are read from the memory cell array, so that an error, having occurred in the data, may be corrected.

However, there is a limitation in a bit number capable of correcting an error on the basis of the error correction code, and when a plurality of means for correcting a bit error are provided, since the sizes of the means for the error correction become very large, it is not suitable for a small electronic apparatus, or since an operation time for the error correction becomes very long, it may have an adverse influence on an operation speed of an entire electronic apparatus.

### SUMMARY

Various embodiments may be directed to an error correction device and an error correction method including a means capable of correcting only a single bit error. After the single bit error of data having a predetermined size written in a memory cell array is corrected, when the error correction has not been completed, a process of segmenting the data and performing error correction of the single bit error with respect to the segmented units may be repeated. Accordingly, even when a plurality of bit errors have occurred in write data having a predetermined size, single bit error correction may be repeated for data segments obtained by segmenting the write data, so that error correction for a plurality of bits may be possible.

In an embodiment, an error correction device may be provided. The error correction device may include a single error correction circuit configured to read unit write data indicated by a unit designation signal from a memory cell array as read data, correct a single bit error, and provide corrected data. The error correction device may include a comparison circuit configured to compare the corrected data with the unit write data and provide a comparison result. The error correction device may include a control circuit configured to update and generate the unit designation signal on a basis of the comparison result. The unit designation signal may be generated to indicate at least one of a plurality of segmented data obtained by dividing the unit write data.

In an embodiment, an error correction method may be provided. The error correction method may include reading unit write data indicated by a unit designation signal from a memory cell array as read data. The error correction method may include correcting a single bit error of the read data and providing corrected data. The error correction method may include comparing the corrected data with the unit write data and providing a comparison result. The error correction method may include dividing the unit write data into a plurality of segments on a basis of the comparison result, and updating and generating the unit designation signal to indicate at least one of the segmented data.

In an embodiment, an error correction device may be provided. The error correction device may include a single error correction circuit configured to read unit write data indicated by a unit designation signal from a memory cell array, correct at least one bit error, and provide corrected data. The error correction device may include a comparison circuit configured to compare the corrected data with the unit write data and provide a comparison result. The error correction device may include a control circuit configured to update and generate the unit designation signal on a basis of the comparison result. The unit designation signal may be generated to indicate at least one of a plurality of segmented data obtained by dividing the unit write data.

According to various embodiments disclosed in the present document, even when the error correction device includes an error correction means for correcting only a single bit error, since it may be possible to correct a plural-bit error, a complicated means for correcting the plural-bit error is not needed.

According to various embodiments disclosed in the present document, the error correction method sequentially divides write data having a predetermined size into segments having smaller sizes and corrects a single bit error. Since an algorithm for correcting the single bit error may be simpler than an algorithm for correcting the plural-bit error, it may be possible to reduce a time required for the error correction, and in the case of simultaneously correcting the single bit error of the segmented data in a parallel manner, it may also be possible to significantly reduce a time for the error correction.

### BRIEF DESCRIPTION OF THE DRAWINGS

FIG. 1 is a block diagram illustrating a representation of an example of a semiconductor device including an error correction device according to an embodiment.

FIG. 2 is a block diagram illustrating a representation of an example of a single error correction circuit according to an embodiment.

FIG. 3 is a block diagram illustrating a representation of an example of a control circuit according to an embodiment.

FIGS. 4A to 4D are conceptual diagrams for explaining an example of a scheme in which unit write data is sequentially segmented according to an embodiment.

FIGS. 5A to 5E are conceptual diagrams for explaining an example of an operation of an area error state storage circuit of a control circuit according to an embodiment.

FIG. 6 is a flowchart for explaining an error correction method according to an embodiment.

FIG. 7 illustrates a block diagram of an example of a representation of a system employing an error correction device and error correction method with the various embodiments discussed above with relation to FIGS. 1-6.

### DETAILED DESCRIPTION

Hereinafter, an error correction device and an error correction method will be described below with reference to the accompanying drawings through various examples of embodiments.

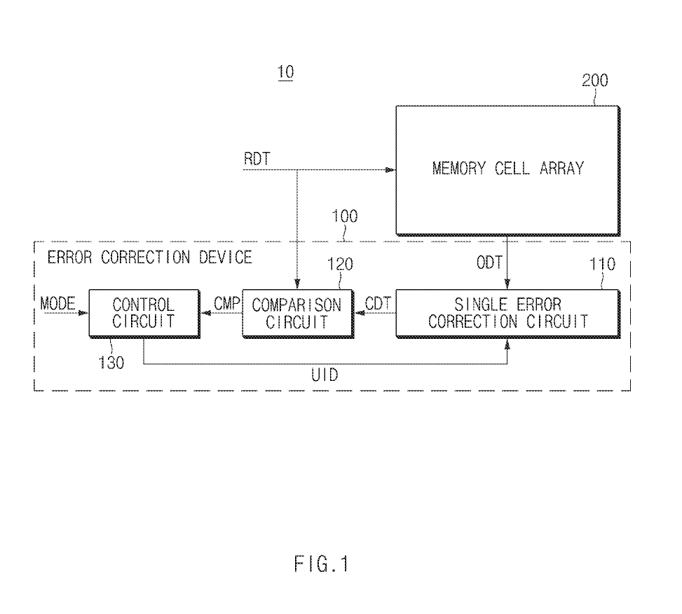

FIG. 1 is a block diagram illustrating a representation of an example of a semiconductor device including an error correction device according to an embodiment.

Referring to FIG. 1, a semiconductor device 10 may include an error correction device 100 and a memory cell array 200.

The semiconductor device 10 may receive write data RDT provided from an exterior, such as, for example, a host. The semiconductor device 10 may receive the write data RDT and write the write data RDT in the memory cell array 200. The write data RDT may be data having a preset size, and an error correction code may be generated on the basis of the write data RDT and may be written in the memory cell array 200.

An error correction code having a bit number corresponding to a predetermined bit number of the write data RDT may be generated according to the type of an error correction code.

The memory cell array 200 may include volatile memory cells such as, for example but not limited to, a SRAM (Static RAM), a DRAM (Dynamic RAM), and a SDRAM (Synchronous DRAM), and nonvolatile memory cells such as a ROM (Read Only Memory), a PROM (Programmable ROM), an EEPROM (Electrically Erase and Programmable ROM), an EPROM (Electrically Programmable ROM), a flash memory, a PRAM (Phase change ROM), a MRAM (Magnetic RAM), a RRAM (Resistive RAM), and a FRAM (Ferroelectric RAM).

The error correction device 100 may include a single error correction circuit 110, a comparison circuit 120, and a control circuit 130.

The single error correction circuit 110 may be configured to read unit write data instructed by a unit designation signal UID from the memory cell array 200 as read data ODT, and correct a single bit error. The single error correction circuit 110 provides the comparison circuit 120 with corrected data CDT obtained by correcting the single bit error.

The unit designation signal UID may be used to instruct that the write data RDT be divided by a predetermined unit. Although the write data RDT has been written in the memory cell array 200, since the value of actually read data may be different from that of the write data RDT, the single error correction circuit 110 reads the read data ODT on the basis of the unit designation signal UID indicating the unit write data corresponding to a part of the entire write data RDT.

The unit designation signal UID is provided from the control circuit 130. The control circuit 130 may designate all write data RDT, which has been initially written in the memory cell array 200 in an initial stage, as the unit write data, designate all positions at which the write data RDT has been written, and generate the unit designation signal UID such that an error correction code generated for the data is read.

As described above, the error correction code may be generated on the basis of the write data RDT and written in the memory cell array 200. In the present specification, the following description will be given on the assumption that the unit designation signal UID designates such that the write data RDT is divided into the unit write data by a predetermined unit, and the unit write data is read as the read data ODT according to the unit designation signal UID. In the present specification, the read data ODT may also be understood as a concept including an error correction code generated for the unit write data designated according to the unit designation signal UID.

Since the single error correction circuit 110 according to an embodiment can correct only a single bit error, only 1-bit error can be corrected for the corrected data CDT generated by correcting an error from the read data ODT.

The comparison circuit 120 compares the corrected data CDT with the unit write data and provides a comparison result CMP. For example, when only one bit-error has existed between the write data RDT and the read data ODT, the unit write data and the corrected data CDT become equal to each other. However, when an error of two bits or more has existed in the read data ODT, the corrected data CDT and the unit write data become different from each other.

The comparison circuit 120 compares the corrected data CDT with the unit write data and provides the comparison result CMP. When the write data RDT is provided to the memory cell array 200, the write data RDT may also be provided to the comparison circuit 120.

The control circuit 130 updates and generates the unit designation signal UID on the basis of the comparison result CMP. The control circuit 130 may divide the unit write data serving as a base for generating the comparison result CMP into a plurality of segments, and generate the unit designation signal UID to designate at least one of the segmented data.

According to embodiments, the unit designation signal UID generated in the control circuit 130 includes the size of the segmented data and the physical or logical position information of the segmented data. The single error correction circuit 110 may read unit write data, which has a size smaller than that of unit write data previously read, as the read data ODT on the basis of the updated and generated unit designation signal UID.

According to embodiments, the control circuit 130 may divide unit write data serving as a base for generating the comparison result CMP, that is, immediately previous unit write data into ½, and generate the unit designation signal UID for designating at least one segmented data as unit write data.

On the basis of the unit designation signal UID provided from the control circuit 130, the single error correction circuit 110 reads read data ODT corresponding to unit write data instructed by the unit designation signal UID from the memory cell array 200. The single error correction circuit 110 corrects a single bit error of the read data ODT and generates corrected data CDT.

The comparison circuit 120 compares the corrected data CDT with the unit write data and generates a comparison result CMP again. Since the size of data has been reduced as compared with previous corrected data CDT, a bit number, in which errors occur, may be reduced, so that all the errors are corrected, resulting in a high probability that the unit write data and the corrected data CDT have the same value.

The control circuit 130 generates the unit designation signal UID to repeat a process of dividing immediately previous unit write data into a plurality of segments and correcting errors until initially written write data RDT and corrected data CDT generated by segmenting the initially written write data RDT become equal to each other on the basis of the comparison result CMP.

As described later, in a process of segmenting the write data RDT and correcting a single bit error, all errors may be corrected for a specific segment of data, but errors may not be corrected for all write data RDT.

The control circuit 130 may generate the unit designation signal UID to repeat a process of storing the comparison result CMP according to areas of a memory cell array corresponding to the unit designation signal UID, dividing only unit write data not completely subjected to error correction into a plurality of segments, and correcting errors.

According to embodiments, the control circuit 130 may receive a mode signal MODE. The mode signal MODE may instruct an initial setting mode and a general operation mode.

The initial setting mode may instruct a scheme in which the process of generating the unit designation signal UID by the control circuit 130 is repeated such that the read data ODT is continuously read for the write data RDT and data having a unit smaller than immediately previous read data is read according to whether errors have been corrected.

The size of unit write data when the error correction device 100 has corrected all the errors of write data RDT may be recognized by the control circuit 130. For example, as a result by initially correcting a single bit error of write data RDT of 128 bits, when read data ODT is read for unit write data RDT of 8 bits to generate corrected data CDT and error correction has been completed for entire write data RDT, the control circuit 130 may store 8 bits which are the size of the unit write data for which the error correction has been completed.

Furthermore, from the start of the general operation mode on the basis of the mode signal MODE, the control circuit 130 may also operate to segment the write data RDT at the size of 8 bits, and to correct a single bit error.

As described above, the error correction device 100 according to an embodiment includes the single error correction circuit 110 capable of correcting only a single bit error, sequentially segments the entire write data RDT, and corrects the single bit error of unit write data having a small size. Consequently, even in the case of including only the single error correction circuit 110 having a simple configuration, it may be possible to correct all errors of the write data RDT including a plural-bit error.

Furthermore, according to embodiments, a plurality of single error correction means may be provided in the single error correction circuit 110, so that a single error correction operation may also be performed for segmented data at a time in a parallel manner.

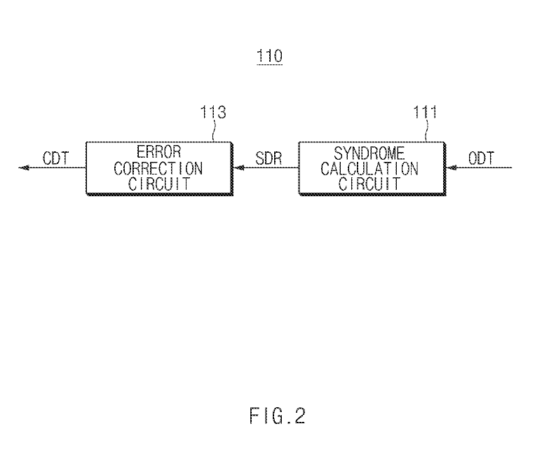

FIG. 2 is a block diagram illustrating a representation of an example of the single error correction circuit according to an embodiment.

Referring to FIG. 2, the single error correction circuit 110 may include a syndrome calculation circuit 111 and an error correction circuit 113.

The syndrome calculation circuit 111 may calculate syndrome data SDR on the basis of the read data ODT and provide the syndrome data SDR to the error correction circuit 113. For example, the single error correction circuit 110 may include a SECDED (Single Error Correction and Double Error Detection) circuit utilizing a Hamming code.

As described above, the read data ODT may include read, which is obtained by reading an area corresponding to unit write data from the memory cell array 200, and an error correction code, that is, a parity bit.

The error correction circuit 113 generates the corrected data CDT from the read data ODT on the basis of the syndrome data SDR. The corrected data CDT may be data obtained by correcting only a single bit error of the read data ODT.

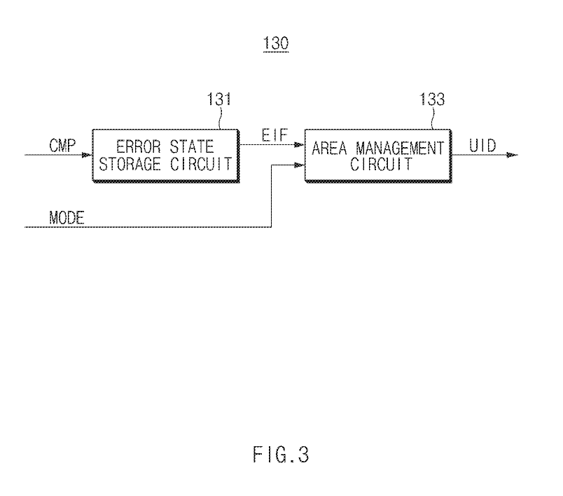

FIG. 3 is a block diagram illustrating a representation of an example of the control circuit according to an embodiment.

Referring to FIG. 3, the control circuit 130 may include an error state storage circuit 131 and an area management circuit 133.

The error state storage circuit 131 may store the comparison result CMP, which has been received from the comparison circuit 120, according to the areas of the memory cell array 200 corresponding to the unit designation signal UID.

The unit designation signal UID may include the size of unit write data and the physical or logical address of the memory cell array 200 corresponding to the unit write data. Accordingly, the error state storage circuit 131 may manage the comparison result CMP according to the areas of the memory cell array 200 corresponding to the unit designation signal UID, thereby understanding data segments for which error correction has not yet been completed.

On the basis of area error information EIF derived from the error state storage circuit 131, the area management circuit 133 may generate the unit designation signal UID to indicate data not completely subjected to error correction and segmented in a specific area of the memory cell array 200.

According to embodiments, since the control circuit 130 may operate in the initial setting mode and the general operation mode, the area management circuit 133 may generate the unit designation signal UID in such a manner that data is sequentially segmented with small sizes or data segments having predetermined sizes are selected on the basis of the mode signal MODE.

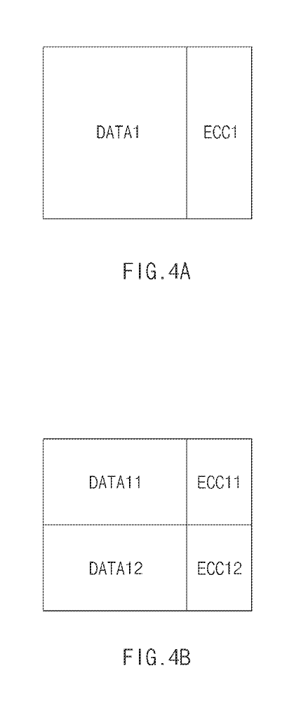

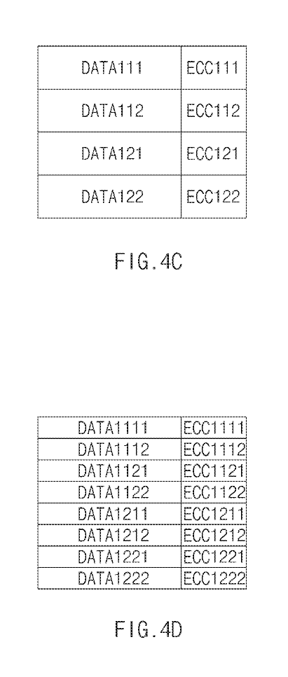

FIG. 4A to FIG. 4D are conceptual diagrams for explaining an example of a scheme in which unit write data is sequentially segmented according to an embodiment.

FIG. 4A illustrates write data RDT initially written in the memory cell array 200 and an error correction code generated for the write data RDT. For the purpose of convenience, the write data RDT and the error correction code are expressed by DATA1 and ECC1.

In an initial setting step of the error correction device 100 according to an embodiment, the control circuit 130 may generate the unit designation signal UID such that all the DATA1 and the ECC1 illustrated in FIG. 4A are read as read data ODT.

If an error has been corrected for the read data ODT but the value is different from that of write data RDT desired to be actually written, the control circuit 130 may segment all the DATA1 and the ECC1 on the basis of the comparison result CMP generated in the comparison circuit 120, and the segmented data may be understood to have a concept as illustrated in FIG. 4A.

Referring to FIG. 4B, the DATA1 may be segmented into DATA11 and DATA12 and error correction codes corresponding to the DATA11 and the DATA12 may be expressed by ECC11 and ECC12. According to embodiments, the DATA11 and the DATA12 may be data having the same size or sizes different from each other, and error correction codes corresponding to the DATA11 and the DATA12 may be decided according to the DATA11 and the DATA12.

The control circuit 130 may generate the unit designation signal UID to select and indicate at least one of the DATA11 and the ECC11, and the DATA12 and the ECC12.

The single error correction circuit 110 repeats a process of reading at least one indicated by the unit designation signal UID between the segmented data as illustrated in FIG. 4B as read data ODT, correcting a single bit error, and generating corrected data CDT.

According to embodiments, the single error correction circuit 110 may firstly read the DATA11 and the ECC11 as the read data ODT on the basis of the unit designation signal UID and generate the corrected data CDT. However, according to other embodiments, the single error correction circuit 110 may read the DATA11 and the ECC11, and the DATA12 and the ECC12 in a parallel manner, and may also simultaneously perform single bit error correction for each of them.

If the error correction has not also been completed for the segmented unit write data as illustrated in FIG. 4B, the control circuit 130 may segment the data into data having a smaller size as illustrated in FIG. 4C and generate the unit designation signal UID to indicate at least one data segment among them.

Similarly, when the error correction has not also been completed for the data segments illustrated in FIG. 4C, the control circuit 130 may segment the data into data having a smaller size as illustrated in FIG. 4C and perform error correction for a single bit.

As described with reference to FIG. 4A to FIG. 4D, in the case in which the size of unit write data, for which single bit error correction is performed, is gradually reduced, when read data ODT for each unit write data is generated as corrected data CDT, it is highly probable that error correction will be completed.

However, when data is segmented with a very small size from the beginning and a single bit error is corrected, unnecessary reading and comparing processes may also be repeated. For example, as a result obtained by generating the corrected data CDT with respect to the DATA12 and the ECC12 illustrated in FIG. 4B, when it is determined that it is the same as the unit write data, it is not necessary to perform an operation and the like for segmenting the DATA12 and the ECC12 with a smaller size as illustrated in FIG. 4C and FIG. 4D and reading data from the memory cell array 200.

Consequently, the error correction device 100 according to an embodiment can perform single bit error correction while moving from a large data unit to a small data unit by passing through the initial setting step, and can omit an unnecessary data correction process.

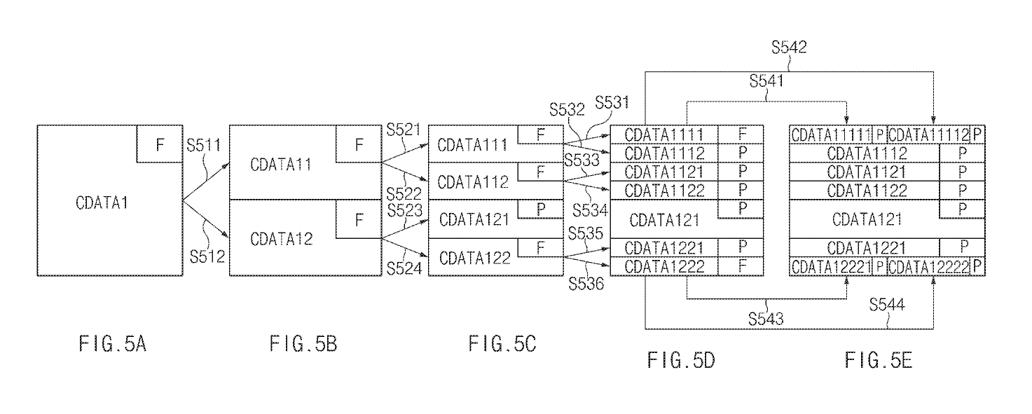

FIGS. 5A to 5E are conceptual diagrams for explaining an example of an operation of the area error state storage circuit of the control circuit according to an embodiment.

Referring to FIGS. 5A to 5E, it can be confirmed that the area error state storage circuit 131 stores a comparison result for each segmented data in a process in which unit write data is segmented such that its size is gradually reduced as described with reference to FIG. 4A to FIG. 4D.

The area error state storage circuit 131 may store a comparison result CMP for a specific area of the memory cell array 200 on the basis of the unit designation signal UID, thereby generating the unit designation signal UID such that an additional error correction process is not performed for data segments for which error correction has been completed.

Referring to FIG. 5A, in an initial state, the single error correction circuit 110 reads read data ODT from unit write data having the same size as that of write data RDT on the basis of a unit designation signal UID. Furthermore, the single error correction circuit 110 generates corrected data CDT as CDATA1 with respect to the read data ODT.

However, as a comparison result of the write data RDT and the CDATA1, when the write data RDT and the CDATA1 are not equal to each other, a comparison result CMP indicating a Fail (F) may be stored in the error state storage circuit 131.

In response to the comparison result CMP, the control circuit 130 may divide the unit write data into a plurality of segments with respect to the entire memory cell array 200 in which the write data RDT has been written, and generate a unit designation signal UID. The data segments may be equal to those illustrated in FIG. 4B.

For example, the area management circuit 133 generates the unit designation signal UID on the basis of area error information EIF of the error state storage circuit 131. The unit designation signal UID generated by the control circuit 130 may designate the DATA11 and the ECC11 (see FIG. 4B) and allow the single error correction circuit 110 to generate CDATA11 (S511). When the unit designation signal UID does not designate the DATA12 and the ECC12 (see FIG. 4B), CDATA12 may be generated later (S512).

As a result obtained when the comparison circuit 120 has compared unit write data corresponding to the DATA11 and the ECC11 (see FIG. 4B) with the CDATA11, when errors have not been corrected, area error information EIF representing that the DATA11 has also failed may be stored, and the area management circuit 133 may segment the data into smaller segments, that is, DATA111 and ECC111, and DATA112 and ECC112 as illustrated in FIG. 4C.

The area management circuit 133 may generate a unit designation signal UID to indicate only the DATA111 and the ECC111 among the segmented data as illustrated in FIG. 4C, and the single error correction circuit 110 may correct errors according to the unit designation signal UID and generate the DATA111 (S521).

When the unit designation signal UID indicates only the DATA111 and the ECC111, CDATA112 may not be generated, and DATA121 and ECC121, and DATA122 and ECC122 illustrated in FIG. 4C may not yet be segmented. Accordingly, S522, S523, and S524 illustrated between FIGS. 5B and 5C may be performed later. In such a case, information regarding comparison results CMP for other areas of the error state storage circuit 131 may be in an empty state.

Referring FIG. 5C, the area management circuit 133 regards that area error information EIF of ‘F’ has been stored for the CDATA111, compares the CDATA11 with the unit write data of the single error correction circuit 110, and determines that error correction has not been completed. Furthermore, the area management circuit 133 may segment the data into DATA1111 and ECC1111, and DATA1112 and ECC1112 as illustrated in FIG. 4D and generate a unit designation signal UID to indicate at least one of them.

As the unit designation signal UID indicates the DATA1111 and the ECC1111, the single error correction circuit 110 may read the read data ODT and generate the DATA1111 (S531), but the unit write data indicated by the unit designation signal UID and the DATA1111 are determined not to coincide with each other and area error information EIF of ‘F’ is stored in the error state storage circuit 131 with respect to the CDATA1111.

Steps (S541 and S542), in which the data is segmented again according to the comparison result CMP and CDATA11111 and CDATA11112 are generated for the data, may be repeated. All the DATA11111 and the CDATA11112 become equal to the unit write data, so that area error information EIF representing Pass (P) is stored in the error state storage circuit 131.

In the above, the case, in which the unit designation signal UID generated by the control circuit 130 indicates only one segmented data as the unit write data and reading and error correction are performed for the data, has been described. However, according to embodiments, the control circuit 130 may generate the unit designation signal UID such that a plurality of pieces of unit write data may be selected at a time and data correction for a single bit may be performed in a parallel manner.

The CDATA11 and the CDATA12 segmented into two between FIGS. 5A and 5B may be substantially and simultaneously generated (S511 and S512). To this end, the single error correction circuit 110 may include two or more single bit error correction means.

Similarly, there may exist a case in which the unit write data segmented into four of the DATA111 and the ECC111, the DATA112 and the ECC112, the DATA121 and the ECC121, and the DATA122 and the ECC122 as illustrated in FIG. 4C may be simultaneously indicated on the basis of the unit designation signal UID.

The single error correction circuit 110 may simultaneously read four pieces of read data ODT and generate the DATA111, the DATA112, the DATA121, and the DATA122 in a parallel manner as illustrated in FIG. 5C (S521, S522, S523, and S524). According to embodiments, the steps may also be performed at different time points.

Since all errors of the DATA121 have been corrected, the data segment is not segmented any more. Accordingly, as illustrated in FIG. 5D, it is possible to confirm that the DATA121 is not segmented any more.

For the DATA111, the DATA112, and the DATA122 from which errors have not yet been corrected, steps of dividing data units into smaller segments and correcting errors may be repeated as indicated in S531 to S536.

Referring to FIG. 5D, the DATA1112, the DATA1121, the DATA1122, and the DATA1221 generated in such a process are determined that all errors have been corrected, so that information of a pass ‘P’ is stored in the error state storage circuit 131.

Only for the DATA1111 and the DATA1222, from which errors have not yet been corrected, steps of segmenting the data and correcting the errors are repeated (S541, S542, S543, and S544).

Since the entire error correction has been completed in FIG. 5E, the control circuit 130 stores unit write data having sizes corresponding to the DATA11111, the DATA11112, the DATA12221, and the DATA12222. Then, in the general operation mode, the write data RDT may be segmented into the unit write data having the stored sizes and an error correction operation may be performed.

As described with reference to FIG. 4A to FIG. 4D and FIGS. 5A to 5E, in the error correction device according to an embodiment, the write data RDT in an initial state is segmented into data having gradually reduced sizes, the error correction process of a single bit is repeated, and operation completion information is stored for data segments subjected to the error correction.

According to such a process, even in the case of including an error correction means for correcting only a single bit, it is possible to correct a plural-bit error included in the write data RDT, and in the case of including a plurality of means for correction a single bit, it is also possible to perform error correction more quickly.

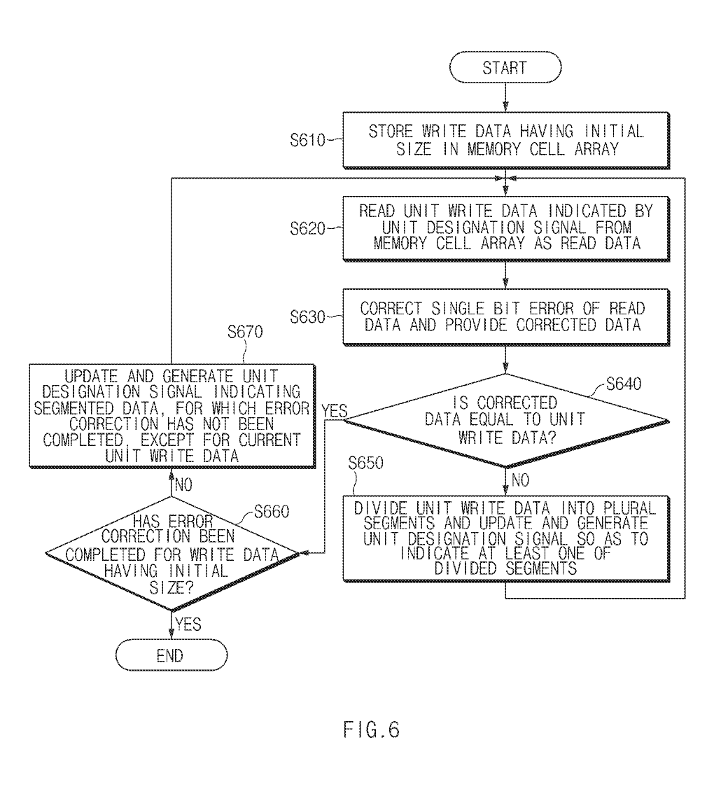

FIG. 6 is a flowchart for explaining an error correction method according to an embodiment.

Referring to FIG. 6, write data RDT having an initial size is stored in the memory cell array 200 (step S610). According to embodiments, a data area and a parity area may be separately provided in the memory cell array 200.

The single error correction circuit 110 of the error correction device 100 reads unit write data indicated by a unit designation signal UID from the memory cell array 200 as read data ODT (step S620).

The single error correction circuit 110 corrects a single bit error of the read data ODT and provides corrected data CDT (step S630).

The comparison circuit 120 determines whether the corrected data CDT and the unit write data indicated by the unit designation signal UID coincide with each other. When the corrected data CDT and the unit write data do not coincide with each other (No of step S640), the comparison circuit 120 generates a comparison result CMP and provides the comparison result CMP to the control circuit 130, so that the control circuit 130 divides the unit write data into a plurality of segments and updates and generates the unit designation signal UID to indicate at least one of the divided segments (step S650), and the aforementioned step S620, step S630, and step S640 are repeated on the basis of the updated unit designation signal UID.

When the corrected data CDT and the unit write data coincide with each other (Yes of step S640), the control circuit 130 may determine whether error correction has been completed for the write data RDT having an initial size on the basis of the error state storage circuit 131 (step S660).

When the entire error correction has been completed for the write data RDT having an initial size (Yes of step S660), all the error correction operations are completed. Furthermore, the smallest size of the unit write data when the error correction operations have been completed may be stored in the control circuit 130 and utilized later for the generation of a unit designation signal UID in the general operation mode.

When the entire error correction has not been completed for the write data RDT having an initial size (No of step S660), the control circuit 130 updates and generates a unit designation signal UID indicating segmented data, for which the error correction has not been completed, except for the current unit write data (step S670), and step S620, step S630, and step S640 may be repeated on the basis of the updated unit designation signal UID.

As described above, in the error correction device and the error correction method according to the embodiments, even when a plurality of error bits exist in write data, the write data is sequentially segmented with small sizes and a signal bit error is corrected, so that it may be possible to correct a plural-bit error.

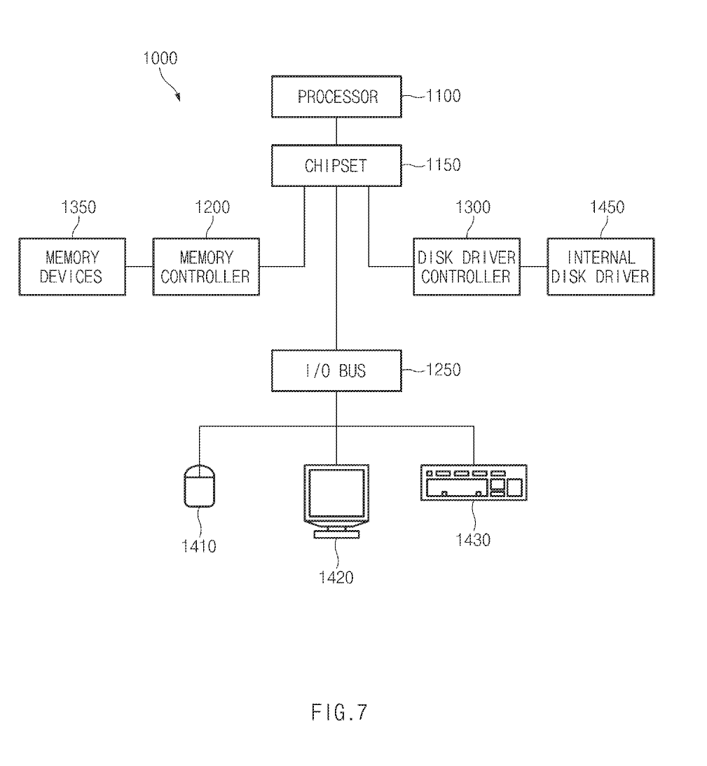

The error correction devices and error correction methods discussed above (see FIGS. 1-6) are particular useful in the design of memory devices, processors, and computer systems. For example, referring to FIG. 7, a block diagram of a system employing an error correction device and/or error correction method in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one an error correction device and/or error correction method as discussed above with reference to FIGS. 1-6. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one an error correction device and/or error correction method as discussed above with relation to FIGS. 1-6, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 7 is merely one example of a system 1000 employing an error correction device and/or error correction method as discussed above with relation to FIGS. 1-6. In alternate embodiments, such as, for example but not limited to, cellular phones or digital cameras, the components may differ from the embodiments illustrated in FIG. 7.

While various embodiments have been described above, it will be understood to those skilled in the art that the embodiments described are by way of example only. Accordingly, the error correction device and the error correction method described herein should not be limited based on the described embodiments.

What is claimed is:

1. An error correction device comprising:
a single error correction circuit configured to read unit write data indicated by a unit designation signal from a memory cell array as read data, correct a single bit error, and provide corrected data;
a comparison circuit configured to compare the corrected data with the unit write data and provide a comparison result; and
a control circuit configured to update and generate the unit designation signal on a basis of the comparison result,
wherein the unit designation signal is generated to indicate at least one of a plurality of segmented data obtained by dividing the unit write data.

2. The error correction device of claim 1, wherein the unit designation signal includes a size and position information of the segmented data.

3. The error correction device of claim 2, wherein the control circuit comprises:
an error state storage circuit that stores the comparison result according to areas of the memory cell array corresponding to the unit designation signal.

4. The error correction device of claim 3, wherein the control circuit comprises:
an area management circuit that generates the unit designation signal to indicate segmented data in an area, in where error correction has not been completed, on the basis of the stored comparison result, so that a single bit error is corrected.

5. The error correction device of claim 4, wherein, when the error correction is performed for write data having a preset size in the memory cell array, the unit designation signal in an initial stage indicates the write data having the preset size.

6. The error correction device of claim 5, wherein the control circuit repeats a process of dividing the data into a plurality of segments and correcting an error until the write data having the preset size and corrected data corresponding to the write data are equal to each other.

7. The error correction device of claim 6, wherein the control circuit decides a size of unit write data in a subsequent operation according to size information of segmented data included in the unit designation signal when the error correction has been completed.

8. The error correction device of claim 2, wherein when dividing the unit write data into a plurality of segments, the control circuit divides the data into two segments having a half data size.

9. The error correction device of claim 2, wherein the single error correction circuit includes a SECDED (Single Error Correction and Double Error Detection) circuit utilizing a Hamming code.

10. The error correction device of claim 1,
wherein the single error correction circuit includes:
a syndrome calculation circuit configured to calculate syndrome data based on the read data; and
an error correction circuit configured to generate the corrected data from the read data based on the syndrome data, and
wherein the corrected is obtained by correcting only a single bit error of the read data.

11. An error correction method comprising the steps of:
reading unit write data indicated by a unit designation signal from a memory cell array as read data;
correcting a single bit error of the read data and providing corrected data;
comparing the corrected data with the unit write data and providing a comparison result; and
dividing the unit write data into a plurality of segments on a basis of the comparison result, and updating and generating the unit designation signal to indicate at least one of the segmented data.

12. The error correction method of claim 11, further comprising a step of:
storing write data having an initial size in the memory cell array.

13. The error correction method of claim 12, wherein, in the step of generating the unit designation signal, until the write data having an initial size and corrected data for the write data are equal to each other, a step of dividing immediately previous segmented data into a plurality of segments and a step of generating the unit designation signal to indicate at least one of the segmented data are repeated.

14. The error correction method of claim 13, wherein the step of dividing immediately previous segmented data into a plurality of segments comprises a step of:
dividing the data into two pieces of data to have a size corresponding to a half of a size of the immediately previous segmented data.

15. The error correction method of claim 13, wherein the error correction method comprises a step of:
storing the comparison result with respect to the unit write data.

16. The error correction method of claim 13, further comprising a step of:
generating an error correction code corresponding to the write data having an initial size and storing the error correction code in the memory cell array.

17. The error correction method of claim 16, wherein the step of providing the read data as the corrected data comprises a step of:
reading the read data and an error correction code corresponding to the unit write data and calculating syndrome data.

18. The error correction method of claim 13, further comprising a step of:
performing a subsequent error correction operation on a basis of a size of data designated by the unit designation signal when the write data having an initial size and the corrected data for the write data are equal to each other.

19. The error correction method of claim 11, wherein reading the unit write data indicated by the unit designation signal from the memory cell array is performed in parallel.

20. An error correction device comprising:
a single error correction circuit configured to read unit write data indicated by a unit designation signal from a memory cell array, correct at least one bit error, and provide corrected data;
a comparison circuit configured to compare the corrected data with the unit write data and provide a comparison result; and
a control circuit configured to update and generate the unit designation signal on a basis of the comparison result,
wherein the unit designation signal is generated to indicate at least one of a plurality of segmented data obtained by dividing the unit write data.
